(19) United States
(12) Patent Application Publication
(10) Pub. No.: US 2016/0168747 A1
(43) Pub. Date: Jun. 16, 2016

(54) APPARATUS AND METHOD FOR MANUFACTURING GROUP 13 NITRIDE CRYSTAL

(71) Applicants: Yusuke MORI, Katano-shi, Osaka (JP); Takashi SATOH, Ohta-ku Tokyo (JP); Masahiro HAYASHI, Tokyo (JP); Seiji SARAYAMA, Tokyo (JP); Yoshikazu KATO, Saitama (JP)

(72) Inventors: Takashi SATOH, Miyagi (JP); Masahiro HAYASHI, Miyagi (JP); Seiji SARAYAMA, Miyagi (JP); Yoshikazu KATO, Saitama (JP); Yusuke MORI, Osaka (JP)

(73) Assignee: RICOH COMPANY, LTD., Tokyo (JP)

(21) Appl. No.: 14/907,887

(22) PCT Filed: Aug. 5, 2014
(86) PCT No.: PCT/JP2014/071134

§ 371 Date: Jan. 27, 2016

(30) Foreign Application Priority Data
Aug. 8, 2013 (JP) 2013-165084

(51) Int. Cl. C30B 9/00; C30B 29/40

(52) U.S. Cl. CPC C30B 9/00; C30B 29/406

(57) ABSTRACT

An apparatus is used for manufacturing a group 13 nitride crystal by using a flux method. The apparatus includes a reaction vessel, a rotational mechanism, and a structure. The reaction vessel contains a mixed melt and a seed crystal placed in the mixed melt. The mixed melt contains an alkali metal or an alkali-earth metal and a group 13 element. The rotational mechanism rotates the reaction vessel. The structure is provided inside the reaction vessel for stirring the mixed melt and is constructed such that a height of a first portion of the structure close to an inner wall of the reaction vessel is higher than a height of a second portion of the structure close to a center of the reaction vessel.

### TECHNICAL FIELD

The present invention relates to an apparatus and a method for manufacturing a group 13 nitride crystal, and in particular, to a technology for manufacturing a group 13 nitride single crystal such as gallium nitride and aluminum nitride.

### BACKGROUND ART

A flux method is known as a method for manufacturing group 13 nitride crystals. In the flux method, a source gas such as a nitrogen gas is dissolved in a mixed melt (flux) containing an alkali metal or an alkali-earth metal and a group 13 metal to form a supersaturated state. In the mixed melt, a group 13 nitride crystal is grown by growing a spontaneous nucleus or by using a seed crystal as a nucleus.

In the flux method, the source gas dissolves into the mixed melt from the vapor-liquid interface between the mixed melt and the source gas, and the concentration of a solute (nitrogen) in the mixed melt tends to increase near the vapor-liquid interface, which is likely to cause solute concentration distribution in the mixed melt. Such solute concentration distribution causes deterioration in the quality of a crystal to be obtained.

As a method for reducing the solute concentration distribution in the mixed melt, a method is known in which a mixed melt is stirred through shaking, rotation, or the like. Patent Literature 1 discloses that a propeller or a baffle is provided in a crucible containing a mixed melt and the mixed melt is stirred aiming at increasing a crystal growth rate and manufacturing a group 13 nitride single crystal in a short time. It is disclosed that a crystal growth rate of 50 to 70 Cm/h in crystal growth over a relatively short period of about 30 to 40 hours has been achieved.

### SUMMARY OF THE INVENTION

However, the inventors of the present invention have found that although performing shaking, stirring, or the like with such a propeller, baffle, or the like as disclosed in Patent Document 1 provided increases the crystal growth rate, the quality such as uniformity of an obtained crystal may degrade. Depending on the shape of the baffle in particular, it has been found that in long-time growth over a few hundred hours, an obtained group 13 nitride crystal may be polycrystallized, or miscellaneous crystals may be precipitated. High quality and large size have been recently demanded as users' needs for the group 13 nitride crystal. To obtain a high-quality, large-sized single group 13 nitride crystal, it is necessary that the mixed melt be maintained at a favorable stirred condition over a long time.

The present invention has been made in view of the above circumstances, and an object thereof is to provide a high-quality, large-sized group 13 nitride single crystal.

According to an embodiment, an apparatus is used for manufacturing a group 13 nitride crystal by using a flux method. The apparatus includes a reaction vessel, a rotational mechanism, and a structure. The reaction vessel contains a mixed melt and a seed crystal placed in the mixed melt. The mixed melt contains an alkali metal or an alkali-earth metal and a group 13 element. The rotational mechanism rotates the reaction vessel. The structure is provided inside the reaction vessel for stirring the mixed melt and is constructed such that a height of a first portion of the structure close to an inner wall of the reaction vessel is higher than a height of a second portion of the structure close to a center of the reaction vessel.

### BRIEF DESCRIPTION OF DRAWINGS

FIG. 1 is a diagram exemplifying the overall configuration of an apparatus for manufacturing a group 13 nitride crystal according to an embodiment of the present invention.

FIG. 2 is a diagram illustrating the internal configuration of a pressure-resistant vessel according to the present embodiment.

FIG. 3 is a diagram illustrating a first example of a baffle according to the present embodiment.

FIG. 4 is a diagram illustrating a second example of the baffle according to the present embodiment.

FIG. 5 is a diagram illustrating a third example of the baffle according to the present embodiment.

FIG. 6 is a diagram illustrating a fourth example of the baffle according to the present embodiment.

FIG. 7 is a diagram illustrating a fifth example of the baffle according to the present embodiment.

FIG. 8 is a diagram illustrating a sixth example of the baffle according to the present embodiment.

FIG. 9 is a diagram illustrating a first example of the arrangement of the baffles according to the present embodiment.

FIG. 10 is a diagram illustrating a second example of the arrangement of the baffles according to the present embodiment.

FIG. 11 is a diagram illustrating a third example of the arrangement of the baffles according to the present embodiment.

FIG. 12 is a diagram illustrating a first example of rotational control of a rotational mechanism according to the present embodiment.

FIG. 13 is a diagram illustrating a second example of the rotational control of the rotational mechanism according to the present embodiment.

FIG. 14 is a diagram illustrating the flow of a mixed melt when a reaction vessel is stopped.

### DESCRIPTION OF EMBODIMENTS

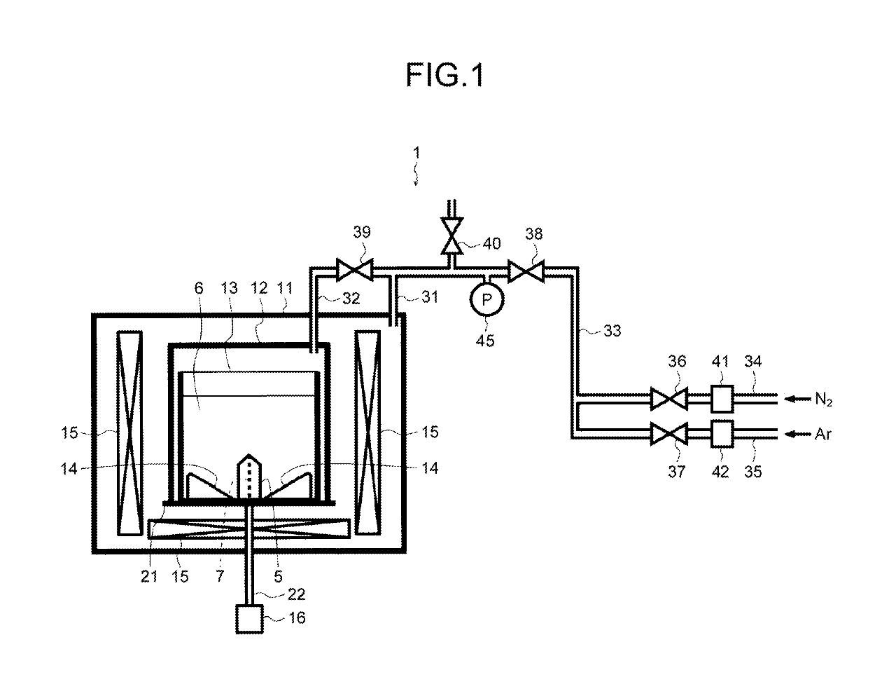

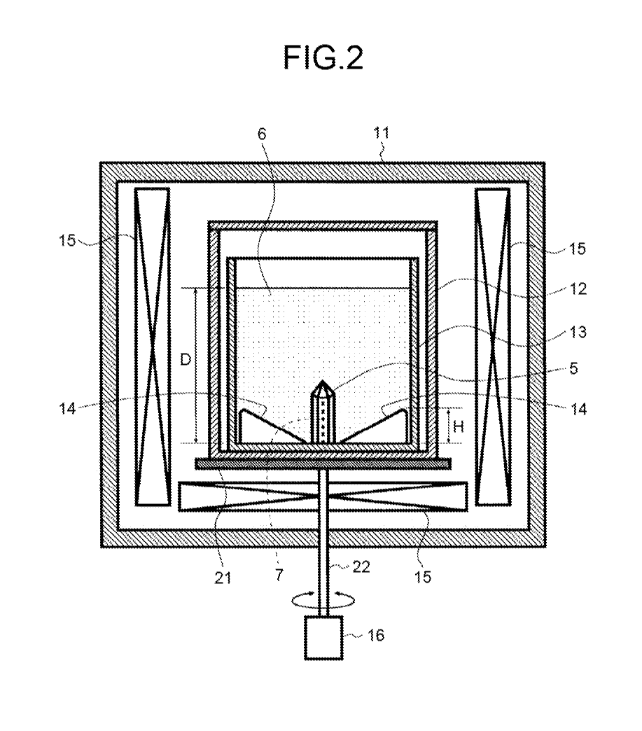

The following describes the embodiment according to the present invention in detail with reference to the drawings. FIG. 1 illustrates the overall configuration of an apparatus 1 for manufacturing a group 13 nitride crystal according to the present embodiment. FIG. 2 illustrates the internal configuration of a pressure-resistant vessel 11 of the manufacturing apparatus 1. The description for FIG. 2 omits pipes 31, 32 that introduce gases from outside the pressure-resistant vessel 11 illustrated in FIG. 1 for the sake of convenience.

The manufacturing apparatus 1 is an apparatus for manufacturing a group 13 nitride crystal 5 by using the flux method. The pressure-resistant vessel 11 is, for example, made of stainless steel. An internal vessel 12 is provided inside the pressure-resistant vessel 11. A reaction vessel 13 is further housed in the internal vessel 12.

The reaction vessel 13 is a vessel used for holding a mixed melt (flux) 6 and growing the group 13 nitride crystal 5. Baffles 14 as structures for stirring the mixed melt 6 are fixed inside the reaction vessel 13 (the baffles 14 are described in detail below).

Examples of the material of the reaction vessel 13 include, but not limited to, nitrides such as boron nitride (BN) sintered bodies and pyrolytic BN (P-BN), oxides such alumina and yttrium-aluminum-garnet (YAG), and carbides such as SiC. It is preferable that an inner wall face of the reaction vessel 13, that is, the part at which the reaction vessel 13 comes into contact with the mixed melt 6 be made of a material that is resistant to reaction with the mixed melt 6. Examples of the material of the inner wall face may include nitrides such as BN, P-BN, and aluminum nitride, oxides such as alumina and YAG, and stainless steel (SUS).

The mixed melt 6 is a melt containing an alkali metal or an alkali-earth metal and a group 13 element. The alkali metal is at least one selected from sodium (Na), lithium (Li), and potassium (K). Preferable is sodium or potassium. The alkali-earth metal is at least one selected from calcium (Ca), magnesium (Mg), strontium (Sr), and barium (Ba). The group 13 element is at least one selected from boron (B), aluminum (Al), gallium (Ga), indium (In), and thallium (Tl). Preferable is gallium. The mixed melt 6 is representatively a Ga—Na mixed melt.

A seed crystal 7 is placed inside the reaction vessel 13 so as to be immersed into the mixed melt 6. In the present embodiment, the seed crystal 7 is fixed to the bottom of the reaction vessel 13. The seed crystal 7 is a nitride crystal serving as a nucleus of the crystal growth of the group 13 nitride crystal 5. Various kinds of seed crystals 7 are known, and what kind of seed crystal 7 is used should be appropriately determined in accordance with a target group 13 nitride crystal 5, growth conditions, and the like. Representative examples of the seed crystal 7 may include a substrate on which a GaN film is formed as a crystal growth layer, and a needle crystal (refer to Japanese Patent Application Laid-open No. 2007-277055 and Japanese Patent Application Laid-open No. 2011-213579, for example).

The internal vessel 12 is detachably provided on a turntable 21 in the pressure-resistant vessel 11. The turntable 21 is fixed to a rotational shaft 22 and is rotatable by a rotational mechanism 16 arranged outside the pressure-resistant vessel 11. The rotational mechanism 16 rotates the rotational shaft 22 by a motor or the like. The rotational velocity, rotational direction, and the like of the rotational shaft 22 are controlled by a controller including a computer operating in accordance with a computer program, various kinds of logic circuits, and the like (the control of the rotational shaft 22 is described in detail below). Along with the rotation of the rotational shaft 22, the internal vessel 12, the reaction vessel 13, the baffle 14, and the like rotate. The members that rotate along with the rotation of the rotational shaft 22 are not limited to these. For example, a heater 15 may further rotate, or only the reaction vessel 13 may rotate. Through the rotation of the baffle 14 along with the rotation of the reaction vessel 13, the mixed melt 6 is stirred.

A source gas including nitrogen is supplied into the pressure-resistant vessel 11. As illustrated in FIG. 1, pipes 31, 32 that supply a nitrogen (N₂) gas as a source of the group 13 nitride crystal 5 and a diluent gas for total pressure adjustment are connected to the internal space of the pressure-resistant vessel 11 and the internal space of the internal vessel 12, respectively. The pipe 33 branches into a nitrogen supply pipe 34 and a diluent gas supply pipe 35. The nitrogen supply pipe 34 and the diluent gas supply pipe 35 have valves 36, 37, respectively. The diluent gas is preferably an argon (Ar) gas as an inert gas, and without being limited thereto, may be helium (He), neon (Ne), or the like.

The nitrogen gas flows into the pipe 34 from a gas cylinder or the like, and the pressure thereof is adjusted by a pressure controller 41. Then the nitrogen gas flows into the pipe 33 via the valve 36. The diluent gas flows into the pipe 35 from a gas cylinder or the like, and the pressure thereof is adjusted by a pressure controller 42. Then, the diluent gas flows into the pipe 33 via the valve 37. The thus pressure-adjusted nitrogen gas and diluent gas form a gas mixture in the pipe 33.

The gas mixture is supplied to the internal space of the pressure-resistant vessel 11 via a valve 38 and the pipe 31 and is supplied to the internal space of the internal vessel 12 via a valve 39 and the pipe 32 from the pipe 33. The internal space of the internal vessel 12 and the internal space of the reaction vessel 13 are connected with each other in the pressure-resistant vessel 11 and have nearly the same atmosphere and nearly the same pressure. The internal vessel 12 is detachable from the manufacturing apparatus 1. The pipe 31 is connected to the outside via the pipe 33 and a valve 40.

The pipe 33 has a pressure gauge 45. By monitoring the pressure gauge 45, the pressures of the internal spaces of the pressure-resistant vessel 11 and the internal vessel 12 (reaction vessel 13) can be adjusted. Thus, the pressures of the nitrogen gas and the diluent gas are adjusted with the valves 36, 37 and by the pressure controllers 41, 42, respectively, thereby enabling the nitrogen partial pressure in the reaction vessel 13 to be adjusted. The total pressures of the pressure-resistant vessel 11 and the internal vessel 12 can be adjusted, and the total pressure in the internal vessel 12 can be increased to suppress the vaporization of the mixed melt 6 (sodium, for example) in the reaction vessel 13. In other words, the nitrogen partial pressure having an influence on the crystal growth conditions of gallium nitride and the total pressure having an influence on the vaporization of the mixed melt 6 can be separately controlled. Naturally, only the nitrogen gas may be introduced into the reaction vessel without introducing the diluent gas. The overall configuration of the manufacturing apparatus 1 illustrated in FIG. 1 is merely an exemplification, and any alterations to the mechanism that supplies the gas containing nitrogen into the reaction vessel 13 or the like have no influence on the technical scope of the present invention.

As illustrated in FIG. 1, the heater 15 is arranged on the periphery and under the bottom of the internal vessel 12 in the pressure-resistant vessel 11. The heater 15 heats the internal vessel 12 and the reaction vessel 13 to adjust the temperature of the mixed melt 6.

Operation to charge the seed crystal 7, raw materials (the alkali metal or the alkali-earth metal and the group 13 element), additives such as C, and dopants such as Ge into the reaction vessel 13 may be performed with the internal vessel 12 put into a glove box having an atmosphere of an inert gas such as an argon gas. This operation may be performed with the reaction vessel 13 placed in the internal vessel 12.

The molar ratio between the group 13 element and the alkali metal contained in the mixed melt 6 is preferably set so that, but not limited to, the molar ratio of the alkali metal with respect to the total molar number of the group 13 element and the alkali metal is 40% to 95%.

After thus charging the raw materials and the like, the heater 15 is powered on to heat the internal vessel 12 and the reaction vessel 13 up to a crystal growth temperature, then the group 13 element, the alkali metal or the alkali-earth metal, other additives, and the like as the raw materials melt in the internal vessel 12 to produce the mixed melt 6. The source gas with a certain nitrogen partial pressure is brought into contact with the mixed melt 6, thereby dissolving nitrogen into the mixed melt 6. The raw materials thus dissolved into the mixed melt 6 are supplied to the surface of the seed crystal 7, and the crystal growth of the group 13 nitride crystal 5 proceeds.

In such a crystal growth process, the rotational mechanism 16 rotates the reaction vessel 13 and the baffle 14 to stir the mixed melt 6, thereby enabling the nitrogen concentration distribution in the mixed melt 6 to be maintained at a constant level. Crystal growth is performed for a long time in the mixed melt 6 with the uniform nitrogen concentration distribution, thereby enabling a high-quality, large-sized group 13 nitride crystal 5 to be manufactured.

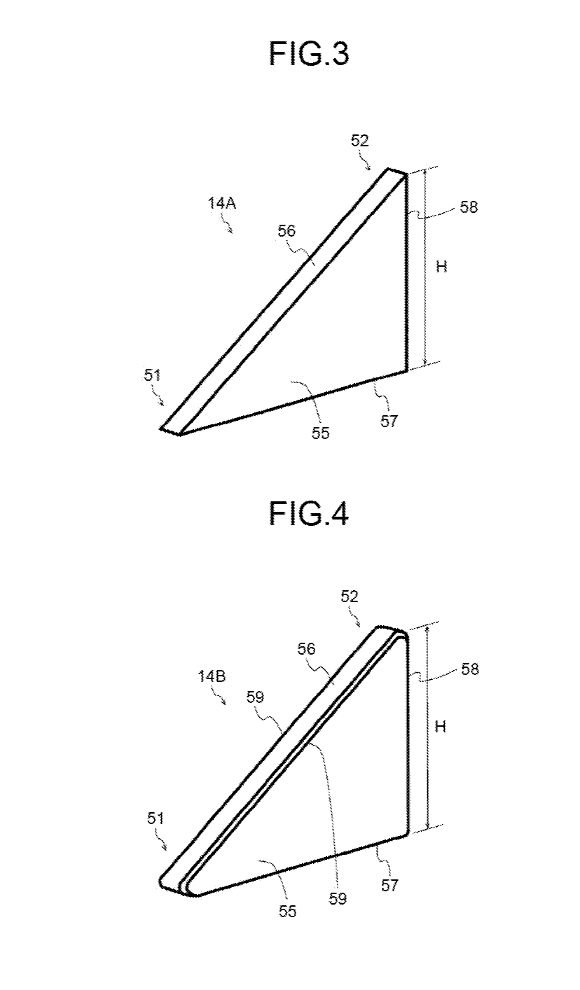

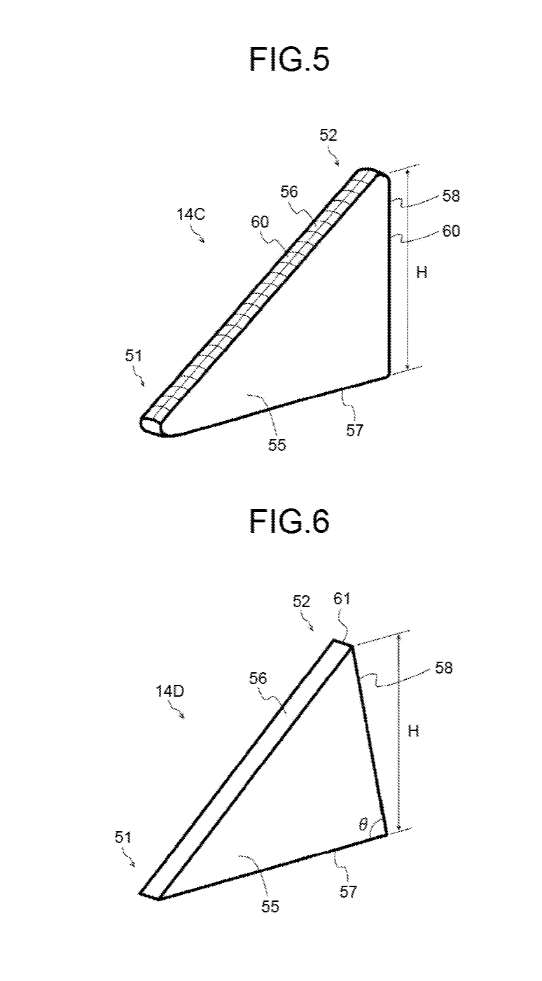

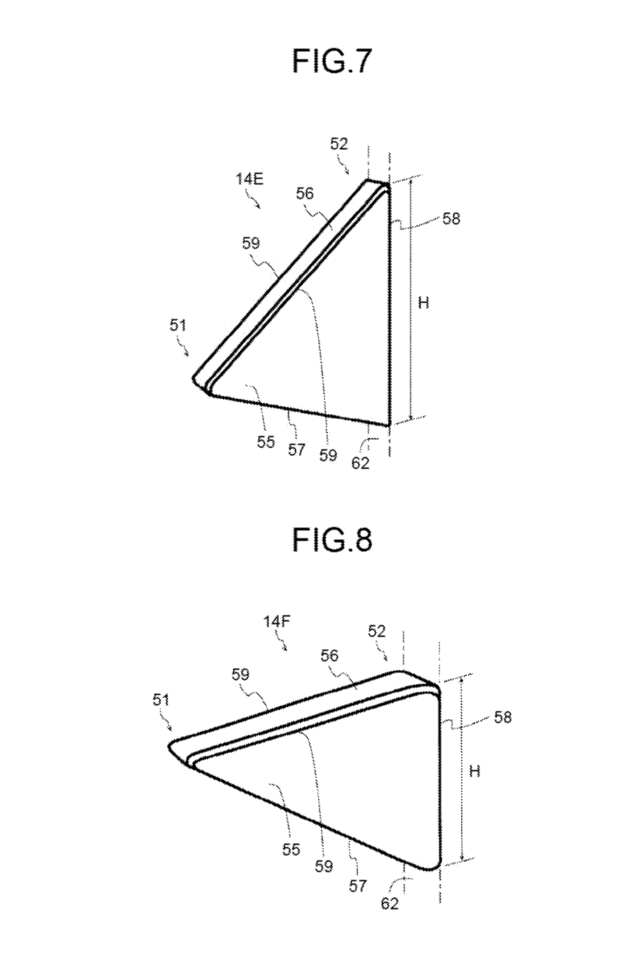

The following describes the shape of the baffle 14 for stirring the mixed melt 6. FIG. 3 illustrates a first example of the baffle 14. FIG. 4 illustrates a second example of the baffle 14. FIG. 5 illustrates a third example of the baffle 14. FIG. 6 illustrates a fourth example of the baffle 14. FIG. 7 illustrates a fifth example of the baffle 14. FIG. 8 illustrates a sixth example of the baffle 14.

These baffles 14A to 14F according to the first to sixth examples illustrated in FIG. 3 to FIG. 8 are common in that the height H of a peripheral portion (a first portion in the claims) 52 is higher than the height of a second portion (a second portion in the claims) 51. The central portion 51 is an end of each of the baffles 14A to 14F close to the center of the reaction vessel 13 or the vicinity of the end. The peripheral portion 52 is an end of each of the baffles 14A to 14F close to the inner periphery (the inner wall) of the reaction vessel 13 or the vicinity of the end. The vicinity of the end refers to a range within a certain distance from the end, and the certain distance refers to a range in which a similar stirring effect can be substantially achieved. This shape enables the mixed melt 6 to be effectively stirred and the nitrogen concentration distribution in the mixed melt 6 to be maintained at a constant level for a long time.

The height H of the peripheral portion 52 is preferably within the range of, with respect to the depth D (refer to FIG. 2) of the mixed melt 6, 0.1≦H/D≦0.85. When H/D is less than 0.1, stirring capability becomes insufficient, which may lead to the inability to sufficiently uniform the mixed melt 6. When H/D exceeds 0.85, the turbulence of the flow of the mixed melt 6 at the vapor-liquid interface increases, which induces production of miscellaneous crystals different from a crystal originally desired to be obtained.

The following describes the characteristics of the baffles 14A to 14F individually. In these different examples, portions that produce the same or similar effect may be referred to as the same reference numeral to omit duplicated description. The baffle 14A according to the first example illustrated in FIG. 3 has two side faces 55, an upper face 56, a lower face 57, and an outer side face 58. The lower face 57 is fixed to the bottom face of the reaction vessel 13. The side faces 55 face the rotational direction of the baffle 14A. The outer side face 58 faces the outer periphery (inner wall face) of the reaction vessel 13 when the lower face 57 is fixed to the bottom face of the reaction vessel 13. The outer side face 58 may be in contact with the inner wall face of the reaction vessel 13 or may be separate therefrom. The upper face 56 inclines so as to be gradually higher from the central portion 51 toward the peripheral portion 52. In the present example, the angle between the lower face 57 and the outer side face 58 is 90 degrees. The side faces 55, the upper face 56, and the outer side face 58 (when being separate from the inner wall face of the reaction vessel 13) are faces that come into contact with the mixed melt 6. The sides as the boundaries among these faces 55, 56, and 58 form nearly the right angles. In other words, the side faces 55 are formed in nearly a right-angled triangular shape. Thus, owing to the shape in which the height H of the peripheral portion 52 is higher than the height of the central portion 51, the mixed melt 6 can be effectively stirred, and the nitrogen concentration distribution in the mixed melt 6 can be maintained uniform for a long time. Although in this drawing the sides as the boundaries between the side faces 55 and the upper face 56 are straight lines, the sides may be curved lines, or the upper face 56 may be a curved face in the present invention. Any shape in which the height of the peripheral portion 52 is higher than the height of the central portion 51 can achieve the above stirring effect.

The baffle 14B according to the second example illustrated in FIG. 4 has chamfered portions 59 on the sides as the boundaries among the side faces 55, the upper face 56, and the outer side face 58. The other portions are the same as the baffle 14A according to the first example. This shape can reduce shear force occurring when the baffle 14B rotates to stir the mixed melt 6 compared with the case of the baffles 14A according to the first example. Reducing the shear force can suppress nucleation, thereby suppressing the polycrystallization different from the crystal originally desired to be obtained of the group 13 nitride crystal 5 and the growth of miscellaneous crystals.

The baffle 14C according to the third example illustrated in FIG. 5 has a curved face 60 as the upper face 56 and the outer side face 58. The other portions are the same as the baffle 14A according to the first example. The faces that come into contact with the mixed melt 6 are thus formed to be such curved faces 60. This can reduce the shear force occurring when the mixed melt 6 is stirred in the same manner as the baffle 14B according to the second example and suppress the polycrystallization different from the crystal originally desired to be obtained and the growth of miscellaneous crystals. When compared with the second example illustrated in FIG. 4, owing to the absence of edges represented by the sectional shape of the baffle, the shear force can be further reduced, thereby suppressing polycrystallization and the growth of miscellaneous crystals.

The baffle 14D according to the fourth example illustrated in FIG. 6 has an angle θ between the lower face 57 and the outer side face 58 of less than 90°, thereby slightly deviating a top side 61 touched by the upper face 56 and the outer side face 58 toward the central side. The other portions are the same as the baffle 14A according to the first example. Specifically, in the present example, the height H of the portion that is slightly close to the center off the outermost portion of the baffle 14D is the largest. This shape can also achieve the stirring effect similar to the baffle 14A according to the first example. In other words, the angle θ between the lower face 57 and the outer side face 58 is not necessarily 90°, and any value close to 90° can achieve the object of the present invention. The value close to 90° is, for example, an angle with an error with 90° of a certain value or less. The certain value is a value within a range in which a similar stirring effect can be achieved. The same holds true for the case of the angle θ exceeding 90°.

In the baffle 14E according to the fifth example illustrated in FIG. 7, the lower face 57 is not fixed to the bottom face of the reaction vessel 13, the outer side face 58 is fixed to an inner wall face 62 of the reaction vessel 13, and the lower face 57 inclines upward with respect to the horizontal direction. The other portions are the same as the baffle 14B according to the second example. This shape can also achieve the effect similar to the baffle 14B according to the second example.

In the baffle 14F according to the sixth example illustrated in FIG. 8, the upper face 56 is horizontal. The other portions are the same as the baffle 14E according to the fifth example. This shape can also achieve the effect similar to the baffle 14E according to the fifth example. In other words, the contact face between the baffle 14 and the reaction vessel 13 may be either the bottom face of the reaction vessel 13 or the inner wall face 62, which is not limited.

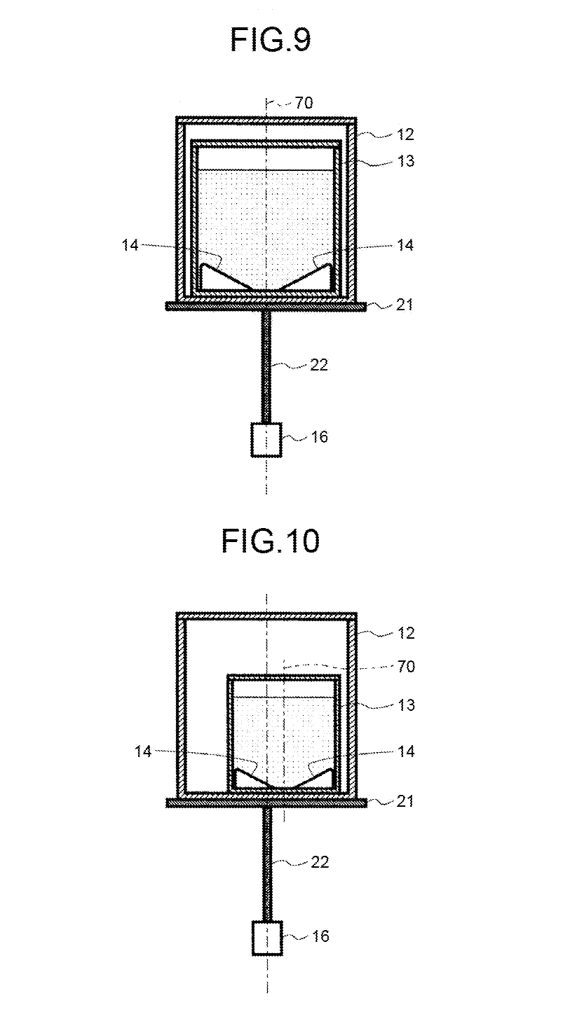

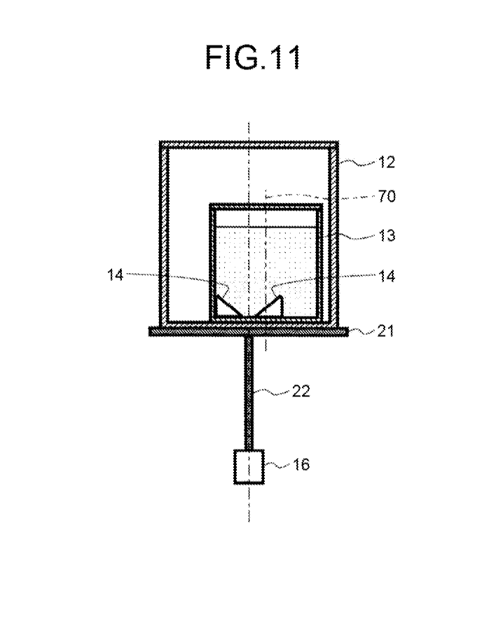

The following describes the arrangement of the baffles 14. FIG. 9 illustrates a first example of the arrangement of the baffles 14. FIG. 10 illustrates a second example of the arrangement of the baffles 14. FIG. 11 illustrates a third example of the arrangement of the baffles 14. In these different examples, portions that produce the same or similar effect may be referred to as the same reference numeral to omit duplicated description.

In the arrangement of the baffle 14 according to the first example illustrated in FIG. 9, the rotational shaft 22 of the rotational mechanism 16 and the central axis 70 of the reaction vessel 13 are coincident with each other, and the plurality of baffles 14 are arranged point-symmetrically with respect to the coincident axis. The baffles 14 are only necessary to be arranged point-symmetrically with respect to the coincident axis and may also be arranged at positions angled with respect to the tangential lines or the normal lines of the bottom face and the side face (inner wall face) of the reaction vessel 13. This arrangement increases the stirring effect and reduces the turbulence of the flow in the mixed melt 6.

In the arrangement of the baffle 14 according to the second example illustrated in FIG. 10, the rotational shaft 22 of the rotational mechanism 16 and the central axis 70 of the reaction vessel 13 are deviated from each other, and the baffles 14 are arranged point-symmetrically with respect to the central axis 70. The baffles 14 are only necessary to be arranged point-symmetrically with respect to the central axis 70 and may also be arranged at positions angled with respect to the tangential lines or the normal lines of the bottom face and the side face (inner wall face) of the reaction vessel 13. The symmetrical center of the baffles 14 is thus made eccentric with respect to the rotational shaft 22 to make the mixed melt 6 asymmetric with respect to the rotational shaft 22. This can produce a faster flow in a part of the mixed melt 6 remote from the rotational shaft 22 than a flow in a part of the mixed melt 6 close to the rotational shaft 22, and the entire mixed melt 6 can be efficiently stirred. However, the turbulence of the flow tends to increase in the part of the mixed melt 6 remote from the rotational shaft 22, and miscellaneous crystals tend to grow. Given this situation, it is preferable that the amount of eccentricity (the amount of deviation between the rotational shaft 22 and the central axis 70) be reduced to the extent that miscellaneous crystals do not grow.

In the arrangement of the baffle 14 according to the third example illustrated in FIG. 11, the rotational shaft 22 of the rotational mechanism 16 and the central axis 70 of the reaction vessel 13 are deviated from each other, and the baffles 14 are arranged point-symmetrically with respect to the rotational shaft 22. The baffles 14 are only necessary to be arranged point-symmetrically with respect to the rotational shaft 22 and may also be arranged at positions angled with respect to the tangential lines or the normal lines of the bottom face and the side face (inner wall face) of the reaction vessel 13. The symmetrical center of the baffles 14 is thus made eccentric with respect to the central axis 70 to make the mixed melt 6 asymmetric with respect to the rotational shaft 22. This can produce a faster flow in the part of the mixed melt 6 remote from the rotational shaft 22 than a flow in the part of the mixed melt 6 close to the rotational shaft 22 in the same manner as the second example, and the entire mixed melt 6 can be efficiently stirred. However, the turbulence of the flow tends to increase in the part of the mixed melt 6 remote from the rotational shaft 22 in the same manner as the second example, and miscellaneous crystals tend to grow. Given this situation, it is preferable that the amount of eccentricity (the amount of deviation between the rotational shaft 22 and the central axis 70) be reduced to the extent that miscellaneous crystals do not grow.

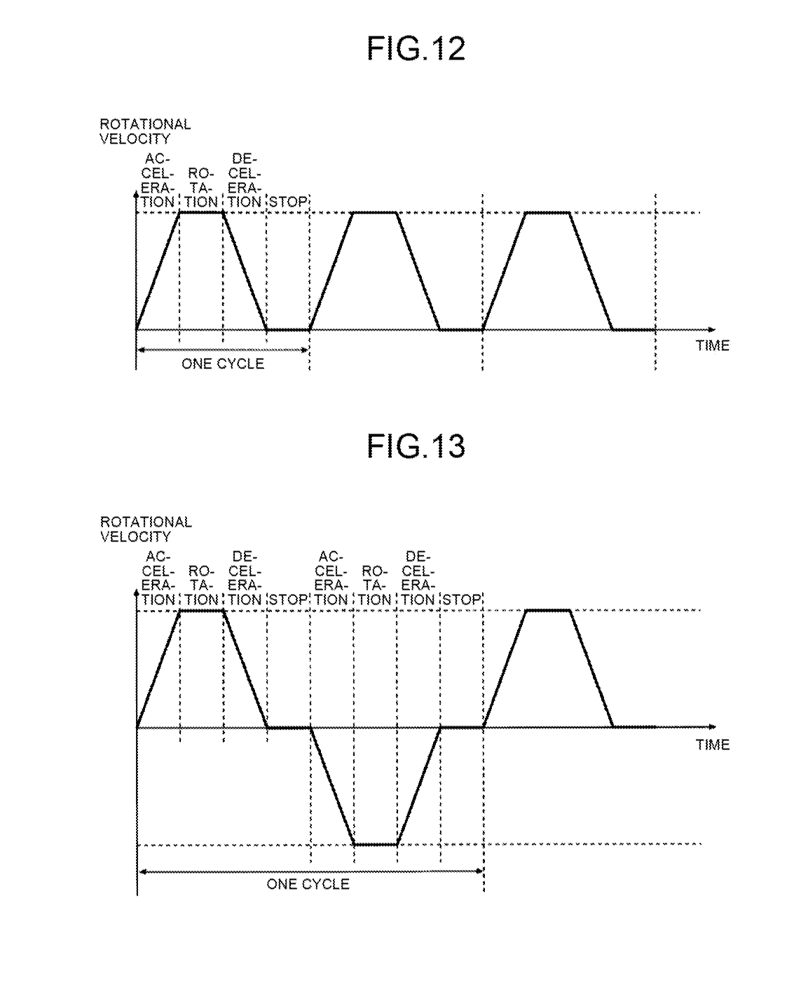

The following describes the rotation control of the rotational shaft 22 by the rotational mechanism 16. FIG. 12 illustrates a first example of the rotation control. FIG. 13 illustrates a second example of the rotation control.

When the baffle 14 is rotated in one direction at a constant velocity, no relative velocity occurs between the mixed melt 6 and the baffle 14, and an ideal flow such as an upward and downward flow of the mixed melt 6 does not occur. Given this situation, it is preferable that rotation control be performed so that the baffle 14 repeats rotation, stop, and the like, thereby producing the relative velocity between the mixed melt 6 and the baffle 14.

The rotation control according to the first example illustrated in FIG. 12 repeats one cycle consisting of acceleration in a first rotational direction from a stopped state, rotation at a predetermined velocity, deceleration from the predetermined velocity to a stopped state, and the hold of the stopped state. This rotation control is performed to produce the relative velocity between the mixed melt 6 and the baffle 14, thereby enabling the mixed melt 6 to be stirred efficiently. This first example repeats the rotation in the same direction.

The rotation control according to the second example illustrated in FIG. 13 repeats one cycle consisting of acceleration in a first direction from a stopped state, the hold of rotation at a predetermined velocity, deceleration from the predetermined velocity to a stopped state, the hold of the stopped state, acceleration in a second rotational direction opposite to the first rotational direction from the stopped state, rotation at a predetermined velocity, deceleration from the predetermined velocity to a stopped state, and the hold of the stopped state. This rotation control is performed, thereby enabling the mixed melt 6 to be stirred more efficiently than the first example illustrated in FIG. 12.

The following describes examples manufacturing the group 13 nitride crystal 5 using the manufacturing apparatus 1 according to the present embodiment.

### Example 1

In the present example, a gallium nitride (GaN) crystal was grown as the group 13 nitride crystal 5 using the baffle 14A illustrated in FIG. 3.

First, in the reaction vessel 13 made of alumina in a glove box with a high-purity Ar atmosphere, four baffles 14A made of alumina having the shape illustrated in FIG. 3 were arranged point-symmetrically with respect to the central axis 70 of the reaction vessel 13. With regard to the planar arrangement, the four baffles 14A were arranged with 90°-symmetry with the central axis 70 as a center when viewing the reaction vessel 13 from above. The baffle 14A is a triangular plate-shaped member having the height H of 35 mm, and the contact face (the lower face 57) with the reaction vessel 13 and the contact face (the side faces 55, the upper face 56, and the outer side face 58) with the mixed melt 6 are all planes. In other words, the sections of the edges of the faces are nearly the right angle.

Next, sodium (Na) liquefied by heating was put into the reaction vessel 13 as the mixed melt 6. After the sodium was solidified, gallium (Ga) and carbon were put thereinto. In the present example, the molar ratio between the gallium and the sodium was set at 0.25:0.75. The carbon was set at 0.5% with respect to the total molar number of the gallium and the sodium.

After that, the reaction vessel 13 was housed in the internal vessel 12, and the internal vessel 12 taken out of the glove box was incorporated into the manufacturing apparatus. As illustrated in FIG. 9, the internal vessel 12 was provided on the turntable 21 in the pressure-resistant vessel 11 so that the central axis 70 of the reaction vessel 13 and the rotational shaft 22 of the rotational mechanism 16 were coincident with each other.

Subsequently, the nitrogen gas pressure in the internal vessel 12 was set at 2.2 MPa, and the heater 15 was powered on to increase the temperature of the reaction vessel 13 to a crystal growth temperature. The temperature was set at 870° C., and the nitrogen gas pressure was set at 3.0 MPa during the crystal growth process.

In this state, as illustrated in FIG. 12, the reaction vessel 13 (the rotational shaft 22) was intermittently rotated in one direction to perform crystal growth for 1,000 hours. The rotational velocity in this situation was set at 15 rpm, and a cycle consisting of acceleration, rotation, deceleration, and stop was repeated for 1,000 hours.

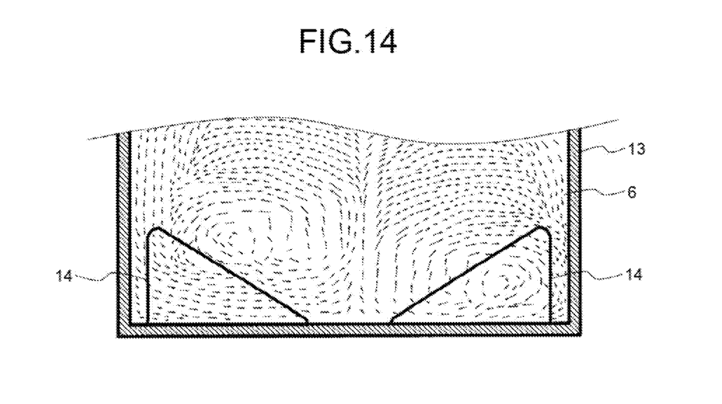

FIG. 14 illustrates the flow of the mixed melt 6 when the reaction vessel 13 is stopped. This drawing exemplifies a result of an experiment performed by irradiating water to which a reflective substance was added with laser light and simulatively visualizing the flow of the mixed melt 6. As illustrated in FIG. 14, the mixed melt 6 produced an upward and downward flow that ascends from its central part and descends from its side face.

The reaction vessel 13 is a cylindrical vessel with an open top. The triangular baffles 14A stood on the bottom face of the reaction vessel 13. Each of the baffles 14A has the height of the peripheral portion 52 is higher than the height of the central portion 51. The mixed melt 6 containing Ga and Na was poured in the reaction vessel 13. The liquid surface of the mixed melt 6 was positioned higher than the maximum height H of the peripheral portion 52 of the baffle 14A, and the entire baffle 14A was immersed into the mixed melt 6. The depth D of the mixed melt 6 was 70 mm. The relation between the depth D and the height H was H/D=0.5.

In this state, the rotation control illustrated in FIG. 12 was performed, thereby forming an upward flow of the mixed melt near the center of the reaction vessel 13 as illustrated in FIG. 14. The inner space of the reaction vessel 13 was filled with a high-pressure nitrogen gas. The mixed melt 6 near the vapor-liquid interface flowed from near the center toward the outer side of the reaction vessel 13. The mixed melt 6 near the inner wall of the reaction vessel 13 flowed toward the bottom face of the reaction vessel 13 as a downward flow. The mixed melt 6 near the bottom face of the reaction vessel 13 flowed from the outer side toward the center. There were almost no turbulent parts and a circulating flow was formed. The circulating flow continued without turbulence during the crystal growth over 1,000 hours.

As described above, the rotation control that repeats rotation and stop was performed using the baffles 14A having the shape illustrated in FIG. 3, thereby stirring the entire mixed melt 6 and distributing nitrogen dissolved from the vapor-liquid interface with a uniform concentration throughout the mixed melt 6. This enabled a high-quality, fast-grown, and highly uniform crystal to grow.

Because the edges of the baffle 14A illustrated in FIG. 3 form nearly the right angle, when the mixed melt 6 and the baffle 14A came into contact with each other, there were cases when the turbulence of the flow was locally formed by shear force. For this reason, there were cases when a highly supersaturated state occurred locally, and miscellaneous crystals grew.

As a result, when a bulky GaN crystal whose length in the c-axial direction was 60 mm and whose length in a direction perpendicular to the c axis was 50 mm was prepared as the group 13 nitride crystal 5, miscellaneous crystals grew at the rate of nearly 15% of the entire yield, and nearly 10% of the grown group 13 nitride crystal 5 were polycrystallized. The prepared bulky GaN crystal was sliced in parallel with the c plane, and XRD measurement was performed thereon. It was revealed that a GaN crystal was obtained having small variations in FWHM and peak position of XRC across the entire c plane. The FWHM of XRC for the GaN crystal except the polycrystallized part in this case was 30±10 arcsec. The dislocation density of the obtained crystal was as low as 10⁴ cm⁻² or less, which was a high-quality crystal.

### Example 2

In the present example, a gallium nitride (GaN) crystal was grown as the group 13 nitride crystal 5 using the baffles 14B illustrated in FIG. 4.

First, in the reaction vessel 13 made of alumina in a glove box with a high-purity Ar atmosphere, four baffles 14B made of alumina illustrated in FIG. 4 were arranged point-symmetrically with respect to the central axis 70 of the reaction vessel 13. With regard to the planar arrangement, the four baffles 14B were arranged with 90°-symmetry with the central axis 70 as center when viewing the reaction vessel 13 from above. Each of the baffles 14B has the height H of the peripheral portion 52 of 35 mm and has the chamfered portions 59 on the edge of the triangle. All the faces 55, 56, 57, 58 of the baffle 14B are planes.

Next, sodium (Na) liquefied by heating was put into the reaction vessel 13 as the mixed melt 6. After the sodium solidified, gallium (Ga) and carbon were put thereinto. In the present example, the molar ratio between the gallium and the sodium was set at 0.25:0.75. The carbon was set at 0.5% with respect to the total molar number of the gallium and the sodium.

After that, the reaction vessel 13 was housed in the internal vessel 12, and the internal vessel 12 taken out of the glove box was incorporated into the manufacturing apparatus. As illustrated in FIG. 9, the internal vessel 12 was provided on the turntable 21 in the pressure-resistant vessel 11 so that the central axis 70 of the reaction vessel 13 and the rotational shaft 22 of the rotational mechanism 16 were coincident with each other.

Subsequently, the nitrogen gas pressure in the internal vessel 12 was set at 2.2 MPa, and the heater 15 was powered on to increase the temperature of the reaction vessel 13 to a crystal growth temperature. The temperature was set at 870° C., and the nitrogen gas pressure was set at 3.0 MPa during the crystal growth process.

In this state, as illustrated in FIG. 12, the reaction vessel 13 (the rotational shaft 22) was intermittently rotated in one direction to perform crystal growth for 1,000 hours. The rotational velocity in this situation was set at 15 rpm, and a cycle consisting of acceleration, rotation, deceleration, and stop was repeated for 1,000 hours. The depth D of the mixed melt 6 was 70 mm. The relation between the depth D and the height H was H/D=0.5.

Also in the present example, the flow of the mixed melt 6 when the reaction vessel 13 was stopped was like a flow illustrated in FIG. 14. The mixed melt near the center of the reaction vessel 13 was an upward flow. The mixed melt 6 near the vapor-liquid interface flowed from near the center toward the outer side of the reaction vessel 13. The mixed melt 6 near the inner wall of the reaction vessel 13 flowed toward the bottom face of the reaction vessel 13 as a downward flow. The mixed melt 6 near the bottom face of the reaction vessel 13 flowed from the outer side toward the center. There were almost no turbulent parts, forming a circulating flow. The circulating flow continued without turbulence during the crystal growth over 1,000 hours.

As described above, by the rotation control that repeats rotation and stop using the baffle 14B having the shape illustrated in FIG. 4, the entire mixed melt 6 was stirred and nitrogen dissolved from the vapor-liquid interface was distributed with an approximately uniform concentration throughout the mixed melt 6. This enabled a high-quality, fast-grown, and highly uniform crystal to grow.

However, the baffle 14B illustrated in FIG. 4 produces local turbulence of a flow when the mixed melt 6 and the baffle 14B come into contact with each other, because of the edges formed by the planes, although the chamfered portions 59 are formed on the edges. Although this turbulence is smaller than that of Example 1, miscellaneous crystals caused by a highly saturated state may occur.

As a result, when a bulky GaN crystal whose length in the c-axial direction was 60 mm and whose length in a direction perpendicular to the c axis was 50 mm was prepared as the group 13 nitride crystal 5, miscellaneous crystals grew at the rate of nearly 10% of the entire yield, and nearly 5% of the grown group 13 nitride crystal 5 were polycrystallized. The growth rate of miscellaneous crystals and the degree of polycrystallization reduced compared with Example 1. This is due to the fact that the chamfered portions 59 were formed on the edges of the baffle 14B, thereby reducing the shear force when the mixed melt 6 was stirred and reducing the turbulence of the flow of the mixed melt 6. The prepared bulky GaN crystal was sliced in parallel with the c plane, and XRD measurement was performed thereon. It was revealed that a GaN crystal was obtained having small variations in FWHM and peak position of XRC across the entire c plane. The FWHM of XRC for the GaN crystal except the polycrystallized part in this case was 30±10 arcsec. The dislocation density of the obtained crystal was as low as 10⁴ cm⁻² or less, which was a high-quality crystal.

### Example 3

In the present example, a gallium nitride (GaN) crystal was grown as the group 13 nitride crystal 5 using the baffles 14C illustrated in FIG. 5.

First, in the reaction vessel 13 made of alumina in a glove box with a high-purity Ar atmosphere, four baffles 14C made of alumina having the shape illustrated in FIG. 5 were arranged point-symmetrically with respect to the central axis 70 of the reaction vessel 13. With regard to the planar arrangement, the four baffles 14C were arranged with 90°-symmetry with the central axis 70 as center when viewing the reaction vessel 13 from above. Each of the baffles 14C has the height H of the peripheral portion 52 of 35 mm and has the curved face 60 as the upper face 56, the outer side face 58, and the edges (sides) of the triangular shape.

Next, sodium (Na) liquefied by heating was put into the reaction vessel 13 as the mixed melt 6. After the sodium solidified, gallium (Ga) and carbon were put thereinto. In the present example, the molar ratio between the gallium and the sodium was set at 0.25:0.75. The carbon was set at 0.5% with respect to the total molar number of the gallium and the sodium.

After that, the reaction vessel 13 was housed in the internal vessel 12, and the internal vessel 12 taken out of the glove box was incorporated into the manufacturing apparatus. As illustrated in FIG. 9, the internal vessel 12 was provided on the turntable 21 in the pressure-resistant vessel 11 so that the central axis 70 of the reaction vessel 13 and the rotational shaft 22 of the rotational mechanism 16 were coincident with each other.

Subsequently, the nitrogen gas pressure in the internal vessel 12 was set at 2.2 MPa, and the heater 15 was powered on to increase the temperature of the reaction vessel 13 to a crystal growth temperature. The temperature was set at 870° C., and the nitrogen gas pressure was set at 3.0 MPa during the crystal growth process.

In this state, as illustrated in FIG. 12, the reaction vessel 13 (the rotational shaft 22) was intermittently rotated in one direction to perform crystal growth for 1,000 hours. The rotational velocity in this situation was set at 15 rpm, and a cycle consisting of acceleration, rotation, deceleration, and stop was repeated for 1,000 hours. The depth D of the mixed melt 6 was 70 mm. The relation between the depth D and the height H was H/D=0.5.

Also in the present example, the flow of the mixed melt 6 when the reaction vessel 13 was stopped was like a flow illustrated in FIG. 14. The mixed melt near the center of the reaction vessel 13 was an upward flow. The mixed melt 6 near the vapor-liquid interface flowed from near the center toward the outer side of the reaction vessel 13. The mixed melt 6 near the inner wall of the reaction vessel 13 flowed toward the bottom face of the reaction vessel 13 as a downward flow. The mixed melt 6 near the bottom face of the reaction vessel 13 flowed from the outer side toward the center. There were almost no turbulent parts, forming a circulating flow. The circulating flow continued without turbulence during the crystal growth over 1,000 hours.

As described above, by the rotation control that repeats rotation and stop using the baffle 14C having the shape illustrated in FIG. 5, the entire mixed melt 6 was stirred and nitrogen dissolved from the vapor-liquid interface was distributed with an approximately uniform concentration throughout the mixed melt 6. This enabled a high-quality, fast-grown, and highly uniform crystal to grow.

The baffle 14C used in the present example produced extremely small turbulence, because almost no shear force occurred when the mixed melt 6 and the baffle 14C came into contact with each other, because the edges of the baffle 14C are the curved face 60.

As a result, when a bulky GaN crystal whose length in the c-axial direction was 60 mm and whose length in a direction perpendicular to the c axis was 50 mm was prepared as the group 13 nitride crystal 5, no miscellaneous crystals grew, and the grown group 13 nitride crystal 5 was not polycrystallized. This is due to the fact that the edges of the baffle 14C are the curved face 60, thereby causing the shear force when the mixed melt 6 was stirred to hardly occur and causing the turbulence of the flow of the mixed melt 6 to be extremely small. When the bulky GaN crystal was sliced in parallel with the c plane, and XRD measurement was performed thereon, it was revealed that a GaN crystal was obtained having small variations in FWHM and peak position of XRC across the entire c plane. The FWHM of XRC for the GaN crystal in this case was 30±10 arcsec. The dislocation density of the obtained crystal was as low as 10⁴ cm⁻² or less, which was a high-quality crystal.

As revealed in Examples 1 to 3, when the edges of the baffle 14 are closer to a curved face, the shear force when the mixed melt 6 and the baffle 14 come into contact with each other reduces, thereby reducing the turbulence of the flow of the mixed melt 6 and producing neither polycrystallization of the group 13 nitride crystal nor the precipitation of miscellaneous crystals. Such an effect can be achieved similarly also when the highest portion of the peripheral portion 52 with the height H is slightly deviated from the outermost portion of the baffle 14D toward the central side as illustrated in FIG. 6. As illustrated in FIG. 7 and FIG. 8, a similar effect can be achieved also when the outer side faces 58 of the baffles 14E and 14F are in contact with the inner wall face 62 of the reaction vessel 13.

### Example 4

In the present example, the baffles 14C made of alumina illustrated in FIG. 5 were arranged point-symmetrically with respect to the central axis 70 of the reaction vessel 13 as illustrated in FIG. 10, and the reaction vessel 13 was arranged so that the rotational shaft 22 of the rotational mechanism 16 and the central axis 70 of the reaction vessel 13 were deviated from each other. The other crystal growth conditions, the rotation control, and the like were the same as those of Example 3.

The central axis 70 of the reaction vessel 13 being different from the rotational shaft 22 made the mixed melt 6 asymmetric with respect to the rotational shaft 22. This enabled a faster flow in the part of the mixed melt 6 remote from the rotational shaft 22 than a flow in the part of the mixed melt 6 close to the rotational shaft 22 to be produced, and the entire mixed melt 6 to be stirred efficiently. However, turbulence increased in the part remote from the rotational shaft 22, and there were cases when miscellaneous crystals grew.

As a result, when a bulky GaN crystal whose length in the c-axial direction was 60 mm and whose length in a direction perpendicular to the c axis was 50 mm was prepared as the group 13 nitride crystal 5, miscellaneous crystals grew at the rate of nearly 20% of the entire yield, and 15% of the grown group 13 nitride crystal were polycrystallized. The present example was different from Example 3 in that although the uniformity of the crystal improved, the growth rate of miscellaneous crystals increased, and the degree of polycrystallization increased. This is due to the fact that the baffles 14C were arranged point-symmetrically with respect to the central axis 70 of the reaction vessel 13, and the reaction vessel 13 was arranged at the position different from the rotational shaft 22. This causes the mixed melt 6 to be stirred efficiently to improve the uniformity of the mixed melt 6. In addition, the turbulence of the mixed melt 6 increased in the part remote from the rotational shaft 22, thereby producing a local highly supersaturated state. The prepared bulky GaN crystal was sliced in parallel with the c plane, and XRD measurement was performed thereon. It was revealed that a GaN crystal was obtained having small variations in FWHM and peak position of XRC across the entire c plane. The FWHM of XRC for the GaN crystal except the polycrystallized part in this case was 30±7 arcsec. The dislocation density of the obtained crystal was as low as 10⁴ cm⁻² or less, which was a high-quality crystal.

### Example 5

In the present example, the baffles 14C made of alumina illustrated in FIG. 5 were arranged point-symmetrically with respect to the rotational shaft 22 of the rotational mechanism 16 as illustrated in FIG. 11, and the reaction vessel 13 was arranged so that the rotational shaft 22 and the central axis 70 of the reaction vessel 13 were deviated from each other. The other crystal growth conditions, the rotation control, and the like were the same as those of Example 3.

The baffles 14C were arranged not with respect to the central axis 70 of the reaction vessel 13 but were arranged point-symmetrically with respect to the rotational shaft 22 of the rotational mechanism 16, thereby making the mixed melt 6 asymmetric with respect to the rotational shaft 22. This enabled a faster flow in the part of the mixed melt 6 remote from the rotational shaft 22 than a flow in the part of the mixed melt 6 close to the rotational shaft 22 to be produced and the entire mixed melt 6 to be stirred efficiently. However, turbulence increased in the part remote from the rotational shaft 22, and there were cases when miscellaneous crystals grew.

As a result, when a bulky GaN crystal whose length in the c-axial direction was 60 mm and whose length in a direction perpendicular to the c axis was 50 mm was prepared as the group 13 nitride crystal 5, miscellaneous crystals grew at the rate of 25% of the entire yield, and 20% of the grown group 13 nitride crystal were polycrystallized. The present example was different from Example 3 in that although the uniformity of the crystal improved, the growth rate of miscellaneous crystals increased, and the degree of polycrystallization increased. This is due to the fact that the baffles 14C were arranged not with respect to the central axis 70 of the reaction vessel 13, and the reaction vessel 13 was arranged so that the baffles 14C were point-symmetric with respect to the rotational shaft 22, thereby stirring the mixed melt 6 efficiently to improve the uniformity of the mixed melt 6 and that the turbulence of the mixed melt 6 increased in the part remote from the rotational shaft 22, thereby producing a local highly supersaturated state. The prepared bulky GaN crystal was sliced in parallel with the c plane, and XRD measurement was performed thereon. It was revealed that a GaN crystal was obtained having small variations in FWHM and peak position of XRC across the entire c plane. The FWHM of XRC for the GaN crystal except the polycrystallized part in this case was 30±7 arcsec. The dislocation density of the obtained crystal was as low as 10⁴ cm⁻² or less, which was a high-quality crystal.

### Example 6

In the present example, the rotation control illustrated in FIG. 13 was performed. The other crystal growth conditions and the like were the same as those of Example 3. In other words, the baffles 14C illustrated in FIG. 5 were arranged point-symmetrically with respect to the axis with which the rotational shaft 22 and the central axis 70 are coincident as illustrated in FIG. 9. For the rotation of the rotational shaft 22, as illustrated in FIG. 13, a cycle consisting of after accelerating, rotating, decelerating, and stopping, followed by accelerating, rotating, decelerating, and stopping in the direction opposite to the immediately preceding rotational direction was repeated. The rotational velocity was set at 15 rpm, and the cycle was repeated for 1,000 hours.

The flow of the mixed melt 6 when the reaction vessel 13 was stopped was like a flow illustrated in FIG. 14. There were almost no turbulent parts, forming a circulating flow. The circulating flow continued without turbulence during the crystal growth over 1,000 hours. The rotation was reversed, thereby improving the uniformity of the entire mixed melt 6.

As described above, using the baffle 14C having the shape illustrated in FIG. 5, the rotation was repeated to be reversed, thereby enabling the entire mixed melt 6 to be stirred efficiently and distributing nitrogen dissolved from the vapor-liquid interface with a uniform concentration throughout the mixed melt 6. This enabled a high-quality, fast-grown, and highly uniform crystal to grow.

As a result, when a bulky GaN crystal whose length in the c-axial direction was 60 mm and whose length in a direction perpendicular to the c axis was 50 mm was prepared as the group 13 nitride crystal 5, no miscellaneous crystals grew, and the grown group 13 nitride crystal 5 was not polycrystallized. The present example was different from Example 3 in that the uniformity of the crystal improved. This is due to the fact that the rotation is repeated to be reversed, thereby enabling the entire mixed melt 6 to be stirred efficiently. When the bulky GaN crystal was sliced in parallel with the c plane, and XRD measurement was performed thereon, it was revealed that a GaN crystal was obtained having small variations in FWHM and peak position of XRC across the entire c plane. The FWHM of XRC for the GaN crystal in this case was 30±5 arcsec. The dislocation density of the obtained crystal was as low as 10⁴ cm⁻² or less, which was a high-quality crystal.

### Example 7

In the present example, the height H of the baffle 14C illustrated in FIG. 5 was set at 6 mm and the relation between the height H and the depth D of the mixed melt 6 was set at H/D=0.086. The other crystal growth conditions, the rotation control, and the like were the same as those of Example 3.

As a result, when a bulky GaN crystal whose length in the c-axial direction was 60 mm and whose length in a direction perpendicular to the c axis was 50 mm was prepared as the group 13 nitride crystal 5, miscellaneous crystals grew at the rate of 25% of the entire yield, and 30% of the grown group 13 nitride crystal were polycrystallized. The present example was different from Example 3 in that the uniformity of the crystal was lowered. This is due to the fact that the height H of the baffle 14C was reduced, thereby lowering stirring capability and lowering the uniformity of the entire mixed melt 6. The prepared bulky GaN crystal was sliced in parallel with the c plane, and XRD measurement was performed thereon. It was revealed that the FWHM and peak position of XRC varied across the entire c plane. The FWHM of XRC for the GaN crystal in this case was 50±15 arcsec.

### Example 8

In the present example, the height H of the baffle 14C illustrated in FIG. 5 was set at 60 mm and the relation between the height H and the depth D of the mixed melt 6 was set at H/D=0.857. The other crystal growth conditions, the rotation control, and the like were the same as those of Example 3.

As a result, when a bulky GaN crystal whose length in the c-axial direction was 65 mm and whose length in a direction perpendicular to the c axis was 55 mm was prepared as the group 13 nitride crystal 5, miscellaneous crystals grew at the rate of 40% of the entire yield, and % of the grown group 13 nitride crystal 5 were polycrystallized. The present example was different from Example 3 in that the growth rate of miscellaneous crystals increased, and the degree of polycrystallization increased. This is due to the fact that the height of the baffle 14C was increased, thereby increasing the turbulence of the flow of the mixed melt 6 at the vapor-liquid interface. The prepared bulky GaN crystal was sliced in parallel with the c plane, and XRD measurement was performed thereon. It was revealed that the FWHM and peak position of XRC varied across the entire c plane. The FWHM of XRC for the GaN crystal except the polycrystallized part in this case was 50±15 arcsec.

As described above, unlike the conventional technology (Patent Document 1), the present embodiment can maintain the mixed melt 6 at a uniform state even when long-time growth over 100 hours or more is performed. This can manufacture a high-quality, large-sized group 13 nitride crystal.

The present invention can provide a high-quality, large-sized group 13 nitride single crystal.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

### REFERENCE SIGNS LIST

1 Apparatus for manufacturing group 13 nitride crystal (manufacturing apparatus)
5 Group 13 nitride crystal
6 Mixed melt
7 Seed crystal
11 Pressure-resistance vessel
12 Internal vessel
13 Reaction vessel
14, 14A, 14B, 14C, 14D, 14E, 14F Baffle (structure)
15 Heater
16 Rotational mechanism
21 Turntable
22 Rotational shaft
31, 32, 33, 34, 35 Pipe
36, 37, 38, 39, 40 Valve
41, 42 Pressure controller
45 Pressure gauge
51 Central portion
52 Peripheral portion
55 Side face
56 Upper face
57 Lower face
58 Outer side face
59 Chamfered portion
60 Curved face
61 Top side
62 Inner wall face
70 Central axis
D Depth (of mixed melt)
H Height (of baffle)

### CITATION LIST

### Patent Literature

Patent Literature 1: WO 2005/080648

1. An apparatus for manufacturing a group 13 nitride crystal by using a flux method, the apparatus comprising:
a reaction vessel that contains a mixed melt and a seed crystal placed in the mixed melt, the mixed melt containing an alkali metal or an alkali-earth metal and a group 13 element;
a rotational mechanism that rotates the reaction vessel; and
a structure that is provided inside the reaction vessel for stirring the mixed melt and is constructed such that a height of a first portion of the structure close to an inner wall of the reaction vessel is higher than a height of a second portion of the structure close to a center of the reaction vessel.

2. The apparatus according to claim 1, wherein the structure is constructed to protrude from a part of a bottom of the reaction vessel toward inside of the reaction vessel.

3. The apparatus according to claim 1, wherein a side of the structure is chamfered.

4. The apparatus according to claim 1, wherein a face of the structure that comes into contact with the mixed melt is a curved face.

5. The apparatus according to claim 1, wherein
the structure is provided in plurality, and
the structures are arranged point-symmetrically with respect to a central axis of the reaction vessel.

6. The apparatus according to claim 1, wherein
the structure is provided in plurality, and
the structures are arranged point-symmetrically with respect to a rotational axis of the rotational mechanism.

7. The apparatus according to claim 1, wherein
the structure is provided in plurality,
the structures are arranged point-symmetrically with a central axis of the reaction vessel, and
the central axis is coincident with a rotational axis of the rotational mechanism.

8. The apparatus according to claim 1, wherein the rotational mechanism operates so that the reaction vessel repeats rotation and stop.

9. The apparatus according to claim 8, wherein the rotational mechanism repeatedly operates so that after the reaction vessel rotates and then stops, the reaction vessel rotates in a same direction as the rotational direction before the stop.

10. The apparatus according to claim 8, wherein the rotational mechanism repeatedly operates so that after the reaction vessel rotates and then stops, the reaction vessel rotates in a direction opposite to the rotational direction before the stop.

11. A method for manufacturing a group 13 nitride crystal, the method comprising:
manufacturing a group 13 nitride crystal with the apparatus for manufacturing a group 13 nitride crystal according to claim 1.
